(19) United States
(12) Patent Application Publication
(10) Pub. No.: US 2013/0115773 A1
(43) Pub. Date: May 9, 2013

(54) Prevention of ILD Loss in Replacement Gate Technologies by Surface Treatmen

(71) Applicants: Rohit Pal, Dresden (DE); Rolf Stephan, Dresden (DE); Andreas Ott, Dresden (DE)

(72) Inventors: Rohit Pal, Dresden (DE); Rolf Stephan, Dresden (DE); Andreas Ott, Dresden (DE)

(73) Assignee: GLOBALFOUNDRIES INC., Grand Cayman (KY)

(21) Appl. No.: 13/289,122

(22) Filed: Nov. 4, 2011

(51) Int. Cl. H01L 21/311

(52) U.S. Cl. 438/697; 257/E21.243

(57) ABSTRACT

When forming sophisticated high-k metal gate electrode structures on the basis of a replacement gate approach, pronounced loss of the interlayer dielectric material may be avoided by inserting at least one surface modification process, for instance in the form of a nitridation process. In this manner, leakage paths caused by metal residues formed in the interlayer dielectric material may be significantly reduced.

### BACKGROUND OF THE INVENTION

1. Field of the Invention

Generally, the present disclosure relates to integrated circuits including transistors with gate electrode structures formed on the basis of replacement gate technology.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, CMOS technology is one of the most promising approaches due to the superior characteristics in view of operating speed and/or power consumption and/or cost efficiency. During the fabrication of complex integrated circuits using, for instance, CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the conductivity of the channel region substantially affects the performance of MOS transistors. Thus, the scaling of the channel length, and associated therewith the reduction of channel resistivity, has been a dominant design criterion for accomplishing an increase in the operating speed of the integrated circuits.

Presently, the vast majority of integrated circuits are based on silicon due to substantially unlimited availability, the well-understood characteristics of silicon and related materials and processes and the experience gathered during the last 50 years. Therefore, silicon will likely remain the material of choice in the near future for circuits designed for mass products. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows subsequent high temperature processes to be performed, as are required, for example, for anneal cycles to activate dopants and to cure crystal damage without sacrificing the electrical characteristics of the interface.

For the reasons pointed out above, in field effect transistors, silicon dioxide is preferably used as a base material of the gate insulation layer that separates the gate electrode, frequently comprised of polysilicon at the interface between the gate dielectric and the electrode material, from the silicon channel region. In steadily improving device performance of field effect transistors, the length of the channel region has been continuously reduced to improve switching speed and drive current capability. Since transistor performance in terms of switching speed and drive current is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be ensured. It turns out that decreasing the channel length requires an increased capacitive coupling to avoid the so-called short channel behavior during transistor operation. Thus, the thickness of the silicon dioxide based layer has to be correspondingly reduced to provide the required capacitance between the gate and the channel region. For example, a channel length of approximately 0.08 μm may require a gate dielectric made on the basis of silicon dioxide as thin as approximately 1.2 nm. For this reason, the relatively high leakage current caused by direct tunneling of charge carriers through an ultra-thin silicon dioxide gate insulation layer may reach values for an oxide thickness in the range of 1-2 nm that may not be compatible with thermal design power requirements for performance-driven circuits.

Therefore, replacing silicon dioxide based dielectrics as the material for gate insulation layers has been considered, particularly for extremely thin silicon dioxide based gate layers. Possible alternative materials include materials that exhibit a significantly higher permittivity so that a physically greater thickness of a correspondingly formed gate insulation layer provides a capacitive coupling that would be obtained by an extremely thin silicon dioxide layer.

Additionally, transistor performance may be increased by providing an appropriate conductive material for the gate electrode so as to replace the usually used polysilicon material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides enhanced channel control, while additionally maintaining leakage currents at an acceptable level. On the other hand, the non-polysilicon material, such as titanium nitride and the like, in combination with other metals, may be formed so as to connect to the high dielectric material, thereby substantially avoiding the presence of a depletion zone. Since the threshold voltage of the transistors, which represents the voltage at which a conductive channel forms in the channel region, is significantly determined by the work function of the metal-containing gate material, an appropriate adjustment of the effective work function with respect to the conductivity type of the transistor under consideration has to be guaranteed.

Providing different metal species for adjusting the work function of the gate electrode structures for P-channel transistors and N-channel transistors at an early manufacturing stage may, however, be associated with a plurality of difficulties, which may stem from the fact that a complex patterning sequence may be required during the formation of the sophisticated high-k metal gate stack, which may result in a significant variability of the resulting work function and thus threshold voltage of the completed transistor structures. For instance, during a corresponding manufacturing sequence, the high-k material may be exposed to oxygen, which may result in an increase of layer thickness and thus a reduction of the capacitive coupling. Moreover, a shift of the work function may be observed when forming appropriate work function metals in an early manufacturing stage, which is believed to be caused by a moderately high oxygen affinity of the metal species, in particular during high temperature processes which may typically be required for completing the transistor structures, for instance for forming drain and source regions and the like.

For this reason, in some approaches, the initial gate electrode stack may be provided with a high degree of compatibility with conventional polysilicon-based process strategies and the deposition of the actual electrode metal, possibly in combination with a high-k dielectric material, and the final adjustment of the work function of the transistors may be accomplished in a very advanced manufacturing stage, i.e., after completing the basic transistor structure. In a corresponding replacement gate approach, the high-k dielectric material, if provided in this stage, may be covered by an appropriate metal-containing material, such as titanium nitride and the like, followed by a standard polysilicon or amorphous silicon material, which may then be patterned on the basis of well-established advanced lithography and etch techniques. Consequently, during the process sequence for patterning the gate electrode structure, the sensitive high-k dielectric material may be protected by the metal-containing material, possibly in combination with sophisticated sidewall spacer structures, thereby substantially avoiding any undue material modification during the further processing. After patterning the gate electrode structure, conventional and well-established process techniques for forming the drain and source regions having the desired complex dopant profile are typically performed. After any high temperature processes, the further processing may be continued, for instance by forming a metal silicide, followed by the deposition of an interlayer dielectric material, such as silicon nitride in combination with silicon dioxide and the like. In this manufacturing stage, a top surface of the gate electrode structures embedded in the interlayer dielectric material has to be exposed, which is accomplished in many approaches by chemical mechanical polishing (CMP). The polysilicon material exposed during the CMP process is then removed and thereafter an appropriate masking regime may be applied in order to selectively fill in an appropriate metal for any type of transistors.

Although in general this approach provides advantages in view of reducing process-related non-uniformities with respect to the threshold voltages of the transistors, since the sensitive metal species for adjusting the work function of the gate electrode structures may be provided after any high temperature processes, the complex process sequence for exposing and replacing the placeholder material may result in a pronounced yield loss, as will be explained in more detail with reference to FIGS. 1a-1d.

FIG. 1a schematically illustrates a cross-sectional view of a semiconductor device 100 in an advanced manufacturing stage, i.e., after completing the basic structure of transistors 150a, 150b. As shown, in this manufacturing stage, the device 100 comprises a substrate 101 in the form of any appropriate carrier material, such as silicon and the like, above which is formed a semiconductor layer 102, for instance comprised of crystalline silicon material and the like. The semiconductor layer 102 may directly connect to a crystalline semiconductor material of the substrate 101 when a bulk configuration is considered, while, in other cases, a buried insulating material (not shown) may be provided so as to form a silicon-on-insulator (SOI) architecture. The semiconductor layer 102 is typically divided into a plurality of active regions, wherein, for convenience, a first active region 102a and a second active region 102b are illustrated in FIG. 1a. Hence, the transistor 150a is formed in and above the active region 102a and comprises drain and source regions and a gate electrode structure 160a formed on the active region 102a. Similarly, the transistor 150b is formed in and above the active region 102b and comprises a gate electrode structure 160b formed on the active region 102b. The transistors 150a, 150b may represent basically the same transistors or transistors of different conductivity type. Moreover, in the manufacturing stage shown, the gate electrode structures 160a, 160b may have basically the same configuration and may comprise a layer or layer system 161, which in some illustrative embodiments is provided merely as a dielectric material that has an etch stop material during the further processing. In other cases, the layers or layer system 161 may comprise a high-k dielectric material, possibly in combination with a metal-containing electrode material, such as titanium nitride and the like, or any other appropriate cap material for protecting the underlying layer or layers. As discussed above, in a replacement gate approach, the gate dielectric material may be formed in a later manufacturing stage or may be provided upon forming the gate electrode structures 160a, 160b in an early manufacturing stage. It should be appreciated that, in other strategies, one of the layer systems 161 may comprise a high-k dielectric material and may provide required electronic characteristics for one type of gate electrode structure, while the other layer or layer system 161 may have to be removed or modified in order to obtain the desired electronic characteristics in a later manufacturing stage.

Furthermore, the gate electrode structures 160a, 160b comprise a placeholder material 162, such as a polysilicon and the like, which is typically followed by a cap layer or cap layer system 164, which is frequently comprised of silicon dioxide, silicon nitride and the like.

Furthermore, a spacer structure 163 of any appropriate configuration is typically provided in the gate electrode structures 160a, 160b in this manufacturing stage. As indicated above, in sophisticated applications, a length of the gate electrode structures 160a, 160b, i.e., in FIG. 1a, the horizontal extension of the placeholder material 162, may be 50 nm and significantly less.

Furthermore, in the manufacturing stage shown, an interlayer dielectric material 120 is formed so as to enclose and thus passivate the gate electrode structures 160a, 160b. For example, frequently, a silicon dioxide material is used as an interlayer dielectric material due to the well-known characteristics of silicon dioxide in combination with a moderately low dielectric constant. Frequently, the interlayer dielectric material 120 may comprise two or more dielectric layers, such as a layer 121, for instance provided in the form of a silicon nitride material and acting as an etch stop material, a strain-inducing material and the like, depending on the overall device and process requirements. Furthermore, a second dielectric layer 122, such as a silicon dioxide material, may be provided. In this manufacturing stage, the gate electrode structures 160a, 160b give rise to a pronounced surface topography, thereby requiring appropriate deposition techniques for forming the interlayer dielectric material 120. For example, well-established chemical vapor deposition (CVD) techniques may be used, while in other cases at least the material 122 may be formed on the basis of spin-on techniques in a low viscous state followed by a corresponding post-deposition treatment in order to achieve the desired material characteristics. In this case, the material 122 may be provided with a substantially planar surface topography, as indicated by 122a.

Basically, the semiconductor device 100 as illustrated in FIG. 1a may be formed on the basis of well-established process strategies. For example, the active regions 102a, 102b may be formed by using any appropriate process technique for providing isolation regions (not shown) and implementing the basic well dopant species using appropriate implantation and masking techniques, followed by the deposition of a plurality of material layers for forming the gate electrode structures 160a, 160b. As discussed above, this may include the deposition of appropriate high-k dielectric materials, possibly in combination with one or more metal-containing electrode materials, if electronic characteristics of one or both of the gate electrode structures 160a, 160b have to be adjusted in this early manufacturing stage. Thereafter, the placeholder material 162 is provided in combination with one or more materials of the cap layer 164, while also additional sacrificial materials may be provided, if required, in order to apply complex patterning strategies for obtaining the desired lateral dimensions of the gate electrode structures 160a, 160b. Thereafter, drain and source regions 151, possibly in combination with the spacer structure 163, may be formed by using well-established implantation techniques, selective epitaxial growth techniques and the like, depending on the overall configuration of the transistors 150a, 150b. After any high temperature processes, typically required for activating the dopants and re-crystallizing implantation-induced damage, in some cases, additional contact areas may be provided in the drain and source regions 151, for example on the basis of a metal silicide, while, in other cases, the interlayer dielectric material 120 may be directly formed on and above the active regions 102a, 102b. As discussed above, to this end, any appropriate deposition strategy may be applied.

Next, a removal process or process sequence is applied so as to remove any excess material of the interlayer dielectric material 120 in order to finally expose the placeholder material 162, which is then removed in order to be replaced by any appropriate material or material system. The exposure of the placeholder material 162 typically involves at least one planarization process on the basis of CMP, wherein typically in a final phase different materials, such as the cap layer 164, the placeholder material 162 and the dielectric material 122 may be present and may thus require highly complex polishing strategies. After exposing the placeholder material 162, highly selective etch recipes are applied, for instance on the basis of TMAH (tetra methyl ammonium hydroxide), ammonium hydroxide and the like, in order to remove the polysilicon material 162 selectively with respect to silicon dioxide, silicon nitride and the like. In other cases, additionally or alternatively, plasma assisted etch recipes may be applied. Although basically the etch strategies are highly selective, nevertheless a pronounced material erosion may occur in the interlayer dielectric material 120, which may thus result in a non-desired surface topography upon removing the polysilicon material 162. Furthermore, in some cases, additional material erosion processes may be intentionally applied in order to provide a superior tapered cross-sectional shape of the resulting gate openings in an upper portion thereof, thereby even further increasing the surface irregularities in the interlayer dielectric material 120.

FIG. 1b schematically illustrates the semiconductor device 100 with corresponding gate openings 160o formed in the gate electrode structures 160a, 160b after removing the placeholder material 162 (FIG. 1a). Furthermore, as discussed above, the interlayer dielectric material 120 may comprise pronounced recesses 120r due to the preceding process sequence for initially exposing the placeholder material 162 and subsequently removing the same in order to provide the gate openings 160o. In some cases, even cavity-like recessed portions may be created in the interlayer dielectric material 120. Next, the layer 161 may be removed if an appropriate gate dielectric material is to be provided, while, in other cases, the one or more materials in the layer 161 may be preserved if complying with the required characteristics of the gate electrode structures 160a, 160b. Irrespective of the process strategy applied, at least one further metal-containing electrode material is to be filled into the gate openings 160o, for instance in the form of aluminum, aluminum alloys and the like. To this end, a plurality of well-established process strategies are available in order to fill one or more metal-containing electrode materials into the gate openings 160o, wherein, as discussed above, possibly the process sequence may be preceded by the formation of a gate dielectric material.

FIG. 1c schematically illustrates the semiconductor device 100 in a further advanced manufacturing stage in which one or more metal-containing electrode materials 165 are formed in and above the gate electrode structures 160a, 160b. As discussed above, a plurality of process strategies may be used, for instance using atomic layer deposition (ALD) techniques for forming layers of work function metal species in a well-defined manner, followed by the deposition of a highly conductive electrode metal and the like. Thereafter, any excess material of the layer 165 is removed, wherein typically, at least in a final phase, a CMP process may be applied.

FIG. 1d schematically illustrates the device 100 in a further advanced manufacturing stage in which the excess material has been removed on the basis of a planarization process, thereby, however, due to the previously created pronounced surface topography, metal residues 165r may still be present in the interlayer dielectric material 120, thereby forming pronounced leakage current paths. In this case, device failures may be observed, for instance, upon forming contact elements in the interlayer dielectric material 120, due to short-circuits caused by the metal residues 165r. On the other hand, a further removal of the metal residues 165r may require a significant reduction of the overall height of the device 100 as shown in FIG. 1d, which is not compatible with the overall device requirements. Hence, in some conventional approaches, it is attempted to reduce the overall material loss in the interlayer dielectric material 120 upon removing the placeholder material 162 (FIG. 1a) by applying etch recipes and cleaning chemistries with superior etch selectivity, which, however, typically have a less pronounced effect with respect to removing surface contaminations and the like. Hence, the overall material loss of the material 120 may be reduced, however, by increasing the overall defect rate, thereby also causing significant irregularities upon completing the gate electrode structures 160a, 160b in a process strategy as described above.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques in which a superior surface topography in the interlayer dielectric material may be obtained upon removing a placeholder material by improving the surface characteristics of the interlayer dielectric material prior to applying one or more critical process steps of the replacement gate approach. In some illustrative aspects disclosed herein, a surface modification may be applied to an exposed surface of the interlayer dielectric material at least once prior to completely removing the placeholder material, thereby imparting at least enhanced etch resistivity to the interlayer dielectric material, however, without unduly modifying the overall dielectric characteristics of the interlayer dielectric material. To this end, a plurality of surface modification techniques, such as plasma treatments, chemical treatments and the like, may be efficiently applied, wherein the effect and the depth of modification may be readily adjusted on the basis of selecting appropriate process parameters.

One illustrative method disclosed herein comprises forming a dielectric layer above a gate electrode structure of a transistor, wherein the gate electrode structure comprises a placeholder material. The method further comprises performing a planarization process so as to remove a portion of the dielectric layer and provide a planarized surface. Additionally, the method comprises performing a surface modification process so as to increase at least an etch resistivity of the planarized surface of the dielectric layer. Moreover, a top surface of the placeholder material is exposed and an etch process is performed so as to remove the placeholder material.

A further illustrative method disclosed herein comprises forming a first portion of an interlayer dielectric material laterally adjacent to a gate electrode structure of a transistor, wherein the gate electrode structure comprises a placeholder material and a dielectric cap layer formed above the placeholder material. The method further comprises performing a surface modification process so as to form a modified surface layer on the first portion of the interlayer dielectric material. The method further comprises forming a second portion of the interlayer dielectric material above the first portion and forming an exposed top surface of the placeholder material by removing a part of at least the second portion and the dielectric cap layer. Additionally, the method comprises replacing the placeholder material with at least a metal-containing electrode material.

A still further illustrative method disclosed herein comprises forming a dielectric material above and laterally adjacent to a gate electrode structure, which comprises a placeholder material. The method further comprises performing a process sequence so as to establish a planarized surface having a modified surface layer, wherein the process sequence comprises performing a planarization process and performing a surface modification process. The process sequence is repeated at least once and a top surface of the placeholder material is then exposed. The method further comprises replacing the placeholder material at least by a metal-containing electrode material.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a semiconductor device during a replacement gate approach on the basis of conventional strategies, which may result in pronounced metal residues;

FIGS. 2a-2e schematically illustrate cross-sectional views of a semiconductor device during various manufacturing stages in applying a replacement gate approach, in which at least one surface modification process is included in order to reduce the material loss upon replacing the placeholder material, according to illustrative embodiments;

FIG. 2f schematically illustrates a cross-sectional view of the semiconductor device according to illustrative embodiments in which at least one surface modification may be applied in an advanced stage of the replacement gate approach, possibly in combination with a sacrificial material;

FIGS. 2g-2h schematically illustrate cross-sectional views of a semiconductor device during various manufacturing stages in which at least one surface modification process may be applied in an intermediate stage of providing the interlayer dielectric material, according to illustrative embodiments; and

FIGS. 2i-2j schematically illustrate cross-sectional views of the semiconductor device according to illustrative embodiments in which a process sequence including a planarization process and a surface modification process may be applied at least twice in order to provide superior surface conditions upon replacing the placeholder material.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates manufacturing techniques in which loss of the interlayer dielectric material may be reduced by inserting at least one surface modification process prior to performing at least some critical steps of the replacement gate approach. To this end, the surface characteristics of the interlayer dielectric material may be enhanced by increasing the etch resistivity and/or the polishing resistivity so that generally a superior surface topography with less material loss is accomplished. In some illustrative embodiments, the surface modification may be accomplished by incorporating a nitrogen species into exposed surface areas of the interlayer dielectric material, which is frequently provided in the form of, at least partially, a silicon dioxide material, so that the incorporation of a nitrogen species results in increased hardness of the surface layer and the like. As explained above, frequently, silicon nitride and silicon dioxide are exposed to various etch recipes and cleaning processes when replacing the placeholder material, wherein generally a silicon nitride material may provide superior resistivity compared to silicon dioxide material, which in turn may be advantageous in terms of dielectric constant and the like. Consequently, in some illustrative embodiments, a nitrogen species is incorporated into exposed surface areas, for which a plurality of well-established process recipes and strategies are available. For example, plasma nitridation is a well-established process in which a plasma ambient is established on the basis of a nitrogen-containing precursor gas, wherein plasma parameters may be efficiently selected so as to control the incorporated amount of nitrogen and the penetration depth thereof. For instance, plasma density, plasma power, pressure and the like may be readily adjusted so as to obtain a desired modification effect on a surface of a material of interest. In other cases, a plurality of nitridation recipes are available on the basis of a pure chemical surface reaction, for instance based on ammonia and the like, wherein the type of reagents, the process temperature and the like may be used for controlling the degree of surface modification. Moreover, since the effect of the surface modification may be restricted to a desired thin surface layer of any exposed material, generally any negative effects on other device areas, such as deeper lying semiconductor materials and the like, may be essentially avoided.

Moreover, since corresponding process tools, such as plasma reactors, chemical reactors and the like, are readily available in a manufacturing environment for processing semiconductor devices, a corresponding surface treatment may be applied at any appropriate stage of the replacement gate approach, substantially without unduly affecting the overall cycle time. Furthermore, in some illustrative embodiments, a surface modification may be applied twice or several times, possibly on the basis of the same process parameters or based on different process parameters at different stages of the replacement gate approach. In this manner, a high degree of flexibility is achieved in order to appropriately adapt the overall process flow to the various process and device requirements.

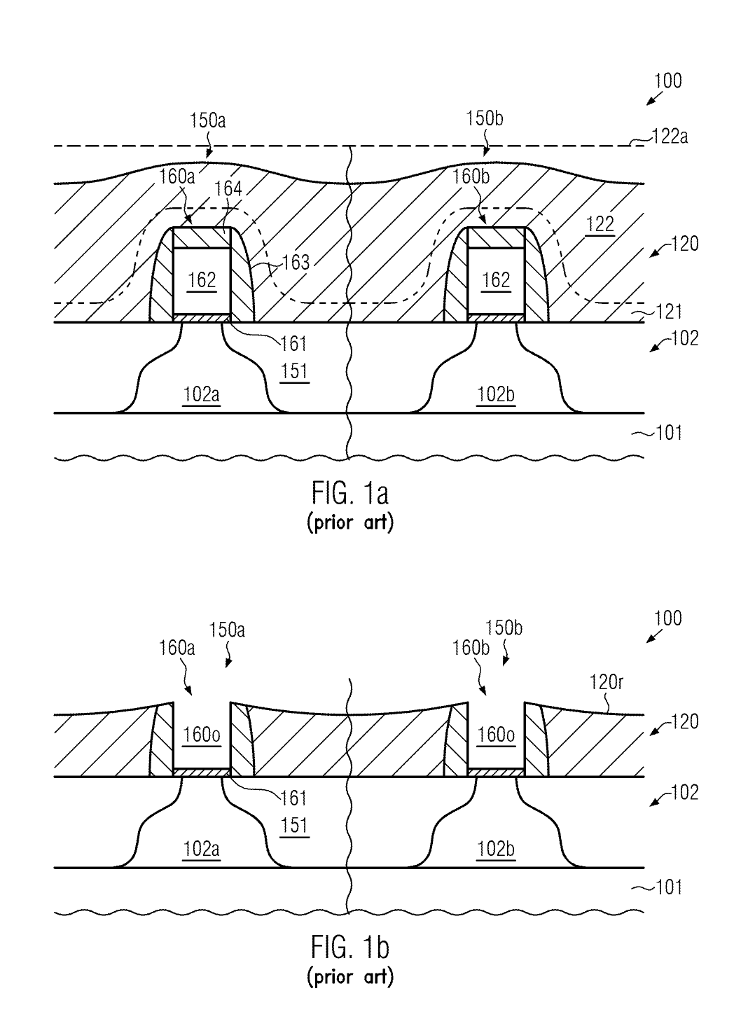

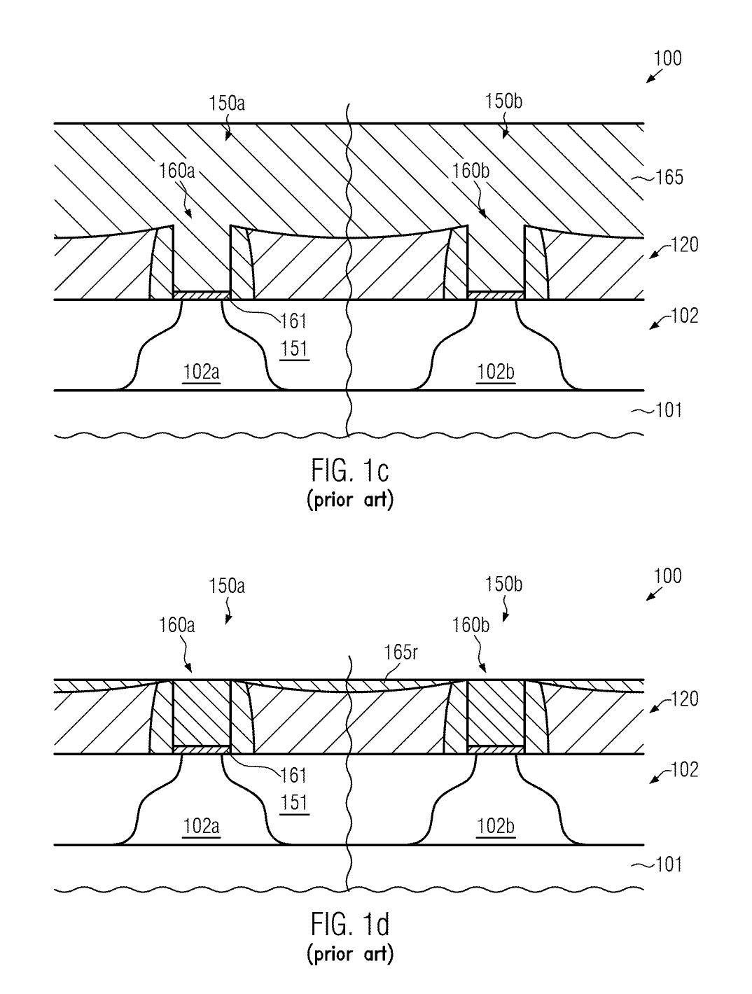

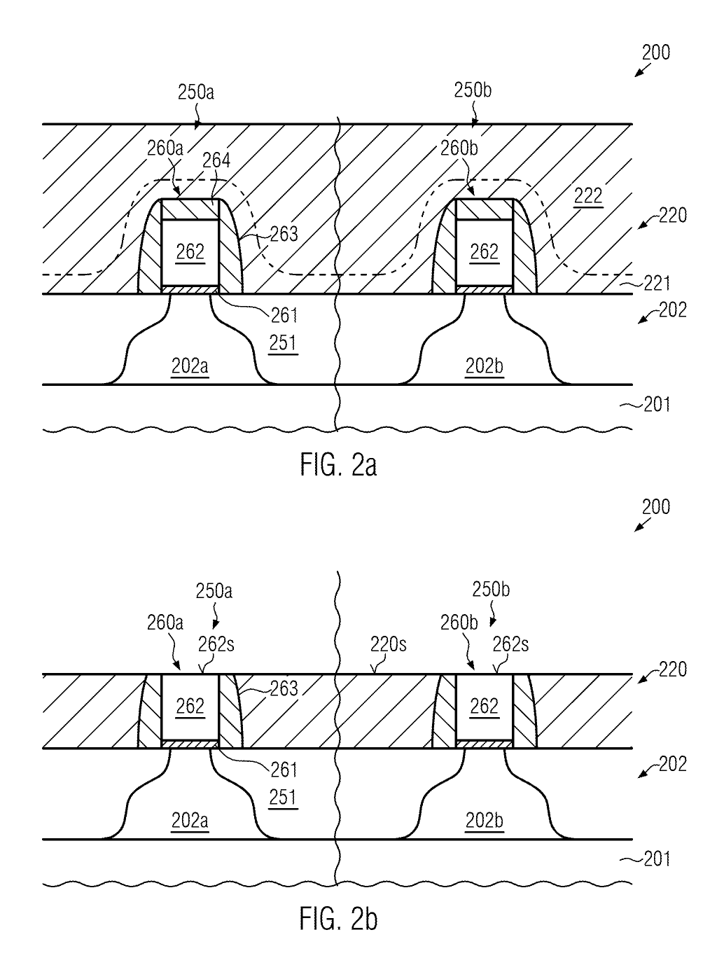

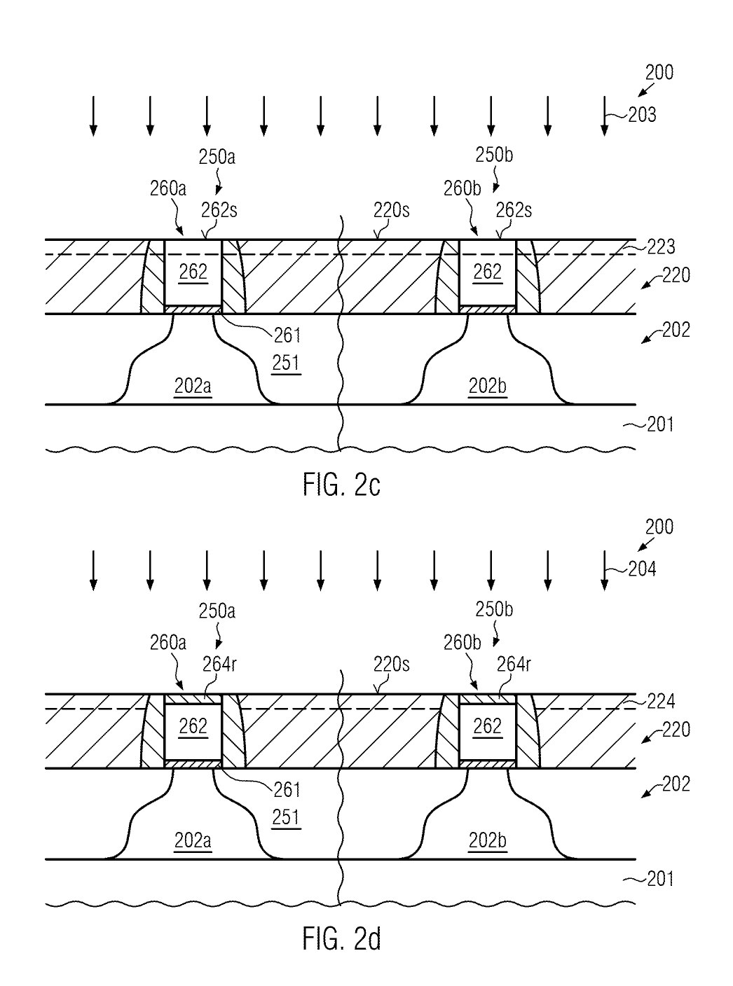

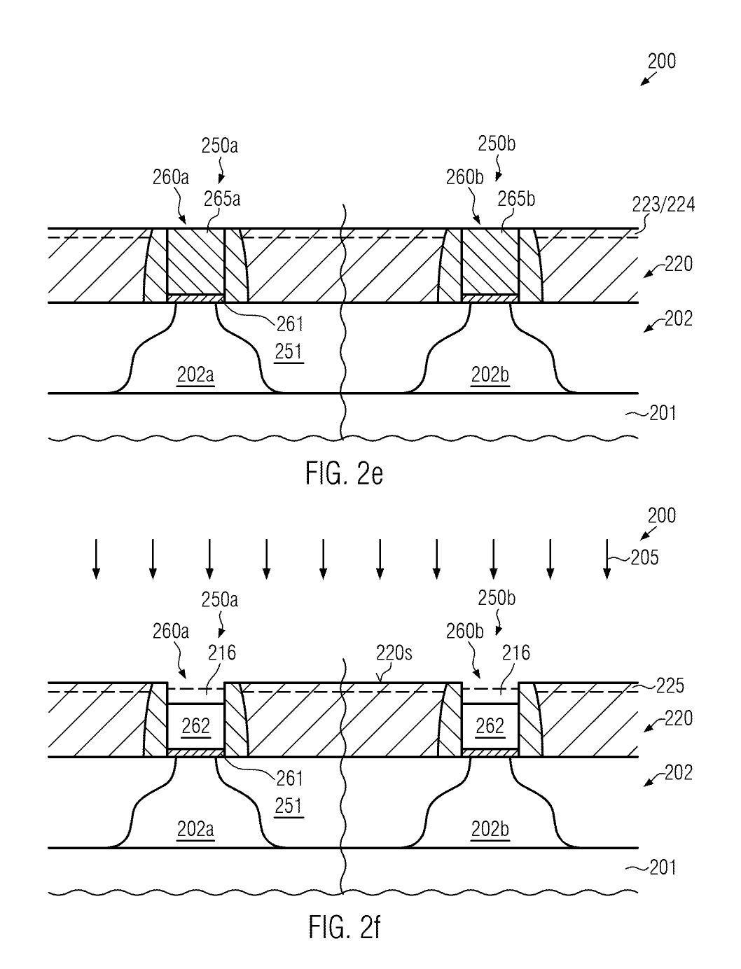

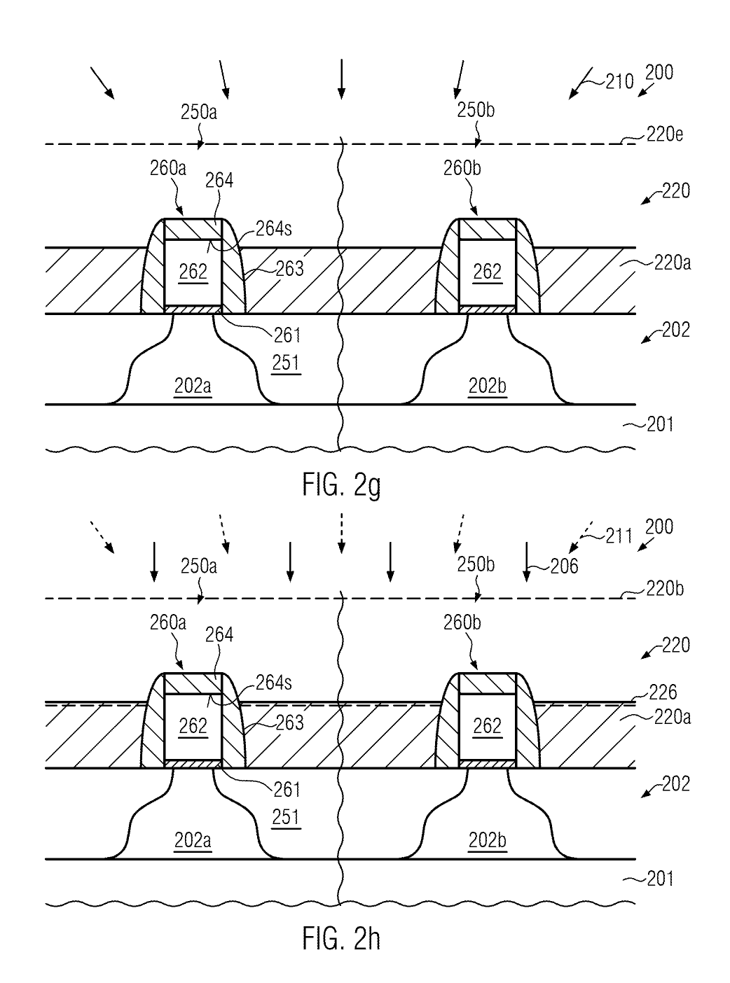

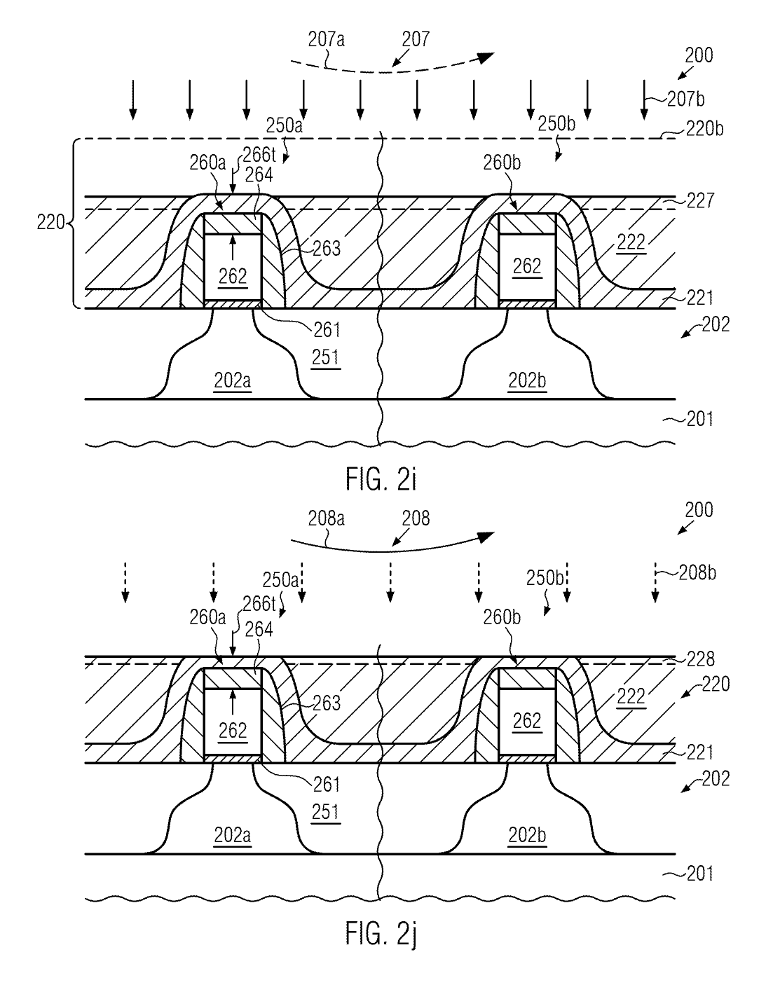

With reference to FIGS. 2a-2j, further illustrative embodiments will now be described in more detail, wherein reference may also be made to FIGS. 1a-1d, if appropriate.

FIG. 2a schematically illustrates a cross-sectional view of a semiconductor device 200 in a manufacturing stage in which the basic configuration of transistors 250a, 250b may be completed, as is also discussed above. Thus, the transistor 250a may be formed in and above an active region 202a and may comprise drain and source regions 251 and a gate electrode structure 260a. Similarly, the transistor 250b may be formed in and above an active region 202b and may comprise a gate electrode structure 260b. As already explained with reference to the device 100, the active regions 202a, 202b may represent any appropriate semiconductor regions in a semiconductor layer 202, in and above which one or more transistors may be formed. Furthermore, the layer 202 may be formed above any appropriate substrate 201, which may form a bulk configuration, an SOI configuration or a combination thereof with the semiconductor layer 202, as is also discussed above. It should further be appreciated that at least one of the transistors 250a, 250b may comprise any performance enhancing mechanisms, such as embedded strain-inducing semiconductor materials (not shown) and the like, as required in accordance with the specifications of the semiconductor device 200. Furthermore, in the manufacturing stage shown, the gate electrode structures 260a, 260b may have basically the same configuration and may comprise a layer or layer system 261, a placeholder material 262 and, in embodiments shown, a cap layer or cap layer system 264. For example, the placeholder material 262 may comprise polysilicon material, a silicon/germanium material and the like. Furthermore, frequently, the cap layer or cap layer system 264 may comprise a silicon nitride material, while, in other cases, a silicon dioxide material may be provided instead of, or in addition to, a silicon nitride material. Moreover, a spacer structure 263 is illustrated, wherein it is to be noted that the spacer structure 263 may have been removed or at least reduced in size in an early manufacturing stage, depending on the overall process and device requirements. Furthermore, an interlayer dielectric material 220 may be provided, which is to be understood as one or more dielectric layers formed around the gate electrode structures 260a, 260b so as to passivate the transistors 250a, 250b and provide an appropriate interface with respect to a metallization system (not shown) still to be formed. For example, the interlayer dielectric material 220 may comprise a first dielectric layer 221, such as a silicon nitride material, and a second dielectric layer 222, such as a silicon dioxide-based material. It should be appreciated, however, that any other dielectric materials may be provided as long as these materials are compatible with the overall device characteristics of the device 200. In the embodiment shown, the surface of the interlayer dielectric material 220 may have a substantially planar configuration, while, in other cases, a more or less pronounced surface topography may be present, which may be reduced, however, by implementing a planarization process, such as a CMP process and the like.

The semiconductor device 200 may generally be formed on the basis of any appropriate process strategy, wherein, in particular, process techniques may be applied as are also discussed above with reference to the semiconductor device 100. Hence, the description of a specific process strategy will be omitted here. Based on the device configuration as shown in FIG. 2a, the processing may be continued by performing a planarization process, for instance including CMP, etching and the like, in order to increasingly remove a portion of the interlayer dielectric material 220 so as to finally expose a top surface of the placeholder material 262, as is also discussed above with reference to the semiconductor device 100. For example, a polishing process based on appropriate chemical slurry materials may be applied in order to first remove the material 222, while subsequently an appropriate polishing recipe may be used for removing the material 222 in combination with the materials of the layers 221 and 264, which may require sophisticated polishing techniques.

FIG. 2b schematically illustrates the device 200 in an advanced manufacturing stage. As shown, a top surface 262s of the placeholder material 262 may be exposed, for instance based on the planarization strategy as described above, while also a more or less planar surface 220s of the interlayer dielectric material 220 is obtained. As explained above with reference to the semiconductor device 100, during the further processing, i.e., upon performing cleaning processes and in particular applying an etch strategy for removing the placeholder material 262, typically, a pronounced material loss may be caused in the material 220 through the surface 220s, in particular when the material 220 may comprise a significant portion of dielectric material having a reduced etch resistivity. For example, as discussed above, frequently, silicon dioxide-based materials are used in the interlayer dielectric material 220, which may have reduced etch resistivity with respect to etch chemistries, cleaning recipes and the like. For example, frequently, very efficient etch or cleaning recipes on the basis of diluted hydrofluoric acid (HF) and the like may have to be applied which, in turn, may result in a corresponding pronounced material loss of a silicon dioxide-based dielectric material, while, on the other hand, a silicon nitride material may provide superior etch resistivity. For this reason, according to some illustrative embodiments, based on the device configuration as shown in FIG. 2b, the exposed surface 220s of the material 220 may be imparted with superior etch resistivity by performing a surface modification process.

FIG. 2c schematically illustrates the semiconductor device 200 when exposed to a process atmosphere 203, which is appropriately configured in order to obtain a desired degree of modification at and below the surface 220s. To this end, in some illustrative embodiments, the surface modification process 203 may be performed on the basis of a plasma atmosphere in order to appropriately activate the surface 220s and initiate the incorporation and chemical reaction of the base material of the layer 220 with at least one atomic species in the atmosphere 203. For example, nitrogen may be incorporated through the surface 220s during a plasma treatment, wherein appropriate process parameters may be readily determined on the basis of experiments or by using well-established process recipes that have been established for nitridation processes. To this end, well-established process tools, such as plasma deposition tools, plasma etch tools and the like, may be used in combination with nitrogen-containing precursor gases, which are appropriately activated in the plasma atmosphere and accelerated towards the surface 220s in order to initiate physical incorporation and chemical reaction, thereby forming a modified surface layer 223 having an enhanced etch resistivity with respect to a plurality of well-established etch chemicals, such as hydrofluoric acid, STM (sulfuric acid/hydrogen peroxide) and the like. Furthermore, typically, the nitrogen-enriched surface layer 223 may also provide superior etch resistivity with respect to highly selective etch recipes that are typically applied for removing the placeholder material 262. Furthermore, based on well-established plasma recipes of the process 203, parameters may be selected so as to adjust the characteristics of the modified surface layer 223, for instance with respect to thickness and degree of modification, thereby enabling a highly flexible adaptation of the characteristics of the layer 223 with respect to a specific process strategy still to be applied to replace the material 262 with at least one metal-containing electrode material.

It should be appreciated that a corresponding modification of an upper portion of the placeholder material 262 may also be initiated during the process 203, and may have a significantly different effect, however, with respect to overall etch resistivity and the like, since the materials 262 and 220 may have a different basic material composition.

In other illustrative embodiments, the process 203 may be applied in the form of a chemical nitridation process, for instance on the basis of ammonia, substantially without requiring the application of a plasma atmosphere prior to or after initiating a chemical reaction so as to form the surface layer 223. Also to this end, a plurality of well-established chemical nitridation recipes are available and may be applied, for instance in the context of a silicon dioxide-based interlayer dielectric material 220.

FIG. 2d schematically illustrates the semiconductor device 200 according to further illustrative embodiments in which a surface modification process 204 may be applied in a different process stage, possibly in addition to or alternatively with respect to the process 203 of FIG. 2c. As shown, in the manufacturing stage shown, the material removal and thus the planarization of the interlayer dielectric material 220 may be discontinued at an earlier stage, thereby preserving a certain portion of the dielectric cap layer or cap layer system, as indicated by 264r. Consequently, in this case, the placeholder material 262 is still reliably covered when performing the surface modification process 204, which may be applied in the form of a plasma assisted process, a chemical process and the like, as discussed above. For example, if the process 204 results in the incorporation of a nitrogen species into exposed areas of the surface 220s, the degree of modification, including the penetration depth of the nitrogen species, may be adjusted, as discussed above, by controlling appropriate process parameters, thereby forming the surface layer 224 having the desired characteristics. On the other hand, a pronounced modification of the placeholder material 262 may be substantially avoided due to the presence of the remaining cap layer 264r, which may comprise a significant portion of silicon nitride material, which per se has a high resistance with respect to the process atmosphere of the treatment 204. In some illustrative embodiments, the parameters of the modification process 204 are selected such that the modified surface layer 224 is formed with a thickness that ensures that the layer 224 extends below the remaining cap layer 264r. In this case, upon further planarizing the interlayer dielectric material 220, a portion of the modified surface layer 224 may be preserved upon exposing the placeholder material 262. In this case, the desired superior surface characteristics of the remaining portion of the layer 224 may still provide superior process conditions upon removing the placeholder material 262, as is already discussed above with reference to FIG. 2c. In other cases, the surface modification process 204 may be applied in combination with the surface modification process 203 so that, for instance, the modification during the process 203 in FIG. 2c may be reduced in its effect, thereby also avoiding a pronounced modification of the surface portion of the placeholder material 262. Hence, on the basis of the device configurations as shown in FIGS. 2c and 2d, the further processing may be continued by replacing the material 262, possibly after completely removing the cap layer 264r in FIG. 2d, wherein any appropriate process strategy may be applied, as is also discussed above with reference to the device 100. Contrary to the conventional strategies, however, at least a portion of the layers 223 and/or 224 may provide enhanced etch resistivity upon removing the material 262, performing cleaning recipes, depositing and possibly patterning one or more materials, such as a high-k dielectric material, work function adjusting materials and the like, thereby reducing the probability of creating metal residues upon depositing highly conductive electrode metals.

FIG. 2e schematically illustrates the semiconductor device 200 in a further advanced manufacturing stage. As shown, the gate electrode structure 260a may comprise one or more metal-containing electrode materials 265a, thereby providing the desired electronic characteristics of the gate electrode structure 260a. Similarly, the gate electrode structure 260b may comprise one or more metal-containing electrode materials 265b so as to achieve the desired characteristics. As discussed above, the layer 261 may be preserved if a high-k dielectric material has already been implemented therein in an earlier manufacturing stage, while, in other cases, the material 261, may be at least partially replaced by any appropriate gate dielectric material, possibly in combination with a work function metal species. Furthermore, as shown, the interlayer dielectric material 220 may still comprise a portion of the previously formed surface layers 223 and/or 224 having the superior etch resistivity, for instance due to the incorporation of a nitrogen species, as discussed above. Consequently, upon performing a planarization process so as to remove any excess material of the materials 265a, 265b, for instance on the basis of a CMP process, the probability of creating any leakage paths may be significantly reduced compared to the conventional strategy as described with reference to FIG. 1 d.

FIG. 2f schematically illustrates the device 200 according to further illustrative embodiments in which a surface modification process 205, such as a nitridation process, may be applied in a still further advanced stage of the replacement gate approach. It should be appreciated that the process 205 may be employed in addition to or alternatively to one or both of the previously described processes 203, 204 (FIGS. 2e and 2d). In the embodiment shown, a portion of the placeholder material 262 may have already been removed and a corresponding removal process may be interrupted by the process 205 in order to “refresh” a previously formed modified surface layer, such as the layers 223, 224 as discussed above with reference to FIGS. 2c and 2d, or to form a new modified surface layer 225, so as to provide superior etch resistivity during the further advance of the replacement gate approach. In some illustrative embodiments, an additional sacrificial fill material 216 may be provided, for instance by spin-on techniques and a subsequent etch-back process, a development process, an evaporation process and the like, so as to avoid an interaction of the process atmosphere 205 with the placeholder material 262. In this manner, the surface modification is substantially restricted to the interlayer dielectric material 220. Consequently, in this case, the further processing may be continued, for instance, by removing the sacrificial material 216 and etching the remaining portion of the material 262, while the refreshed or newly created surface layer 225 imparts superior etch resistivity to the interlayer dielectric material 220.

With reference to FIGS. 2g and 2h, further illustrative embodiments will now be described in which a surface modification process may be applied in an intermediate phase upon providing the interlayer dielectric material.

FIG. 2g schematically illustrates the semiconductor device 200 during a process 210 in which a portion 220a of the interlayer dielectric material may be formed laterally adjacent to the gate electrode structures 260a, 260b, wherein, preferably, a height level of the material 220a is below or at a height level of an interface 264s formed between the cap layer 264 and the placeholder material 262. To this end, the process sequence 210 may comprise an appropriate deposition process so as to form the interlayer dielectric material 220 with a desired height, as indicated by 220e, which may be accomplished by spin-on techniques, by CVD and a subsequent planarization process and the like. Thereafter, the process sequence 210 may comprise an etch process so as to obtain the first portion 220a with a desired height level.

FIG. 2h schematically illustrates the semiconductor device 200 in a further advanced manufacturing stage in which a surface modification process 206 may be applied to the material 220a, thereby forming a modified surface layer 226 having the superior characteristics, for instance by incorporating a nitrogen species into a silicon-based material, as is also discussed above. Moreover, the surface modification process 206 may be applied in the form of a plasma assisted process, a chemical treatment and the like, as is also discussed above. Hence, the surface layer 226 may be positioned at an appropriate height level which may thus ensure that at least a portion of the layer 226 may be preserved during the further processing, in particular when removing the cap layer 264 and exposing the placeholder material 262. Thereafter, the processing may be continued by performing a deposition process 211 in order to provide a second portion 220b of the interlayer dielectric material 220, based on which the above-described process sequence may be applied so as to planarize the material 220 and finally expose the placeholder material 262. If desired, at any appropriate stage of the planarization process, a further surface modification process may be implemented, as, for instance, described above with reference to FIGS. 2c and 2d. Moreover, if desired, during the further processing, the process 205 may be applied, as discussed above with reference to FIG. 2f. Consequently, also in this case, superior surface conditions may be achieved upon removing the placeholder material 262 and depositing one or more metal-containing electrode materials and removing any excess portion thereof.

With reference to FIGS. 2i and 2j, further illustrative embodiments will now be described in which a process sequence including a planarization process and a surface modification process is repeated at least once upon performing a replacement gate approach, thereby increasing flexibility and enhancing overall process conditions.

FIG. 2i schematically illustrates the semiconductor device 200 with the interlayer dielectric material 220, which may comprise a silicon nitride etch stop layer 221 and the silicon dioxide-based dielectric layer 222. In this manufacturing stage, a process sequence 207 may be applied in which a removal or planarization process 207a may reduce the thickness of the interlayer dielectric material 220, for instance by preferably removing the silicon dioxide base material 222. To this end, any well-established etch techniques or CMP process recipes may be applied. Upon exposing the layer 221, which may also be used as a control mechanism for discontinuing the planarization process 207a, a surface modification 207b may be applied, for instance in the form of a nitridation plasma base, chemically initiated and the like, in order to incorporate a nitrogen species, in particular, into exposed portions of the silicon dioxide base material 222. In this case, a surface layer 227 may be efficiently formed, while, for instance, the placeholder material 262 is substantially not influenced by the modification process 207b due to the presence of the cap layer 264 and the dielectric layer 221. Hence, in this manufacturing stage, a thickness 266t of these layers may be sufficient to provide reliable protection of the placeholder material 262. Moreover, the modified surface layer 227 may also have similar characteristics compared to the exposed portions of the layer 221, thereby enhancing the process conditions for the further removal of material of the interlayer dielectric material 220. That is, the surface layer 227 may have silicon nitride-like characteristics and thus may provide more uniform removal of the material 220 compared to conventional strategies in which highly complex planarization recipes are required so as to substantially uniformly remove silicon nitride and silicon dioxide material.

FIG. 2j schematically illustrates the semiconductor device 200 in a further advanced manufacturing stage in which a further process sequence 208 may be applied, which may also comprise a planarization process 208a and a surface modification process 208b. It should be appreciated that, due to the fact that the process 208 also comprises a planarization process and a surface modification process, this process may be considered as a repetition of the process 207 of FIG. 2i, even though different process recipes may be used, if considered appropriate. During the planarization process 208a, the thickness of the interlayer dielectric material 220 is further reduced, thereby obtaining, for instance, a reduced thickness 266t of silicon nitride material above the placeholder material 262 compared to the situation as shown in FIG. 2i. It should be appreciated, however, that, due to the previously formed modified surface layer 227 of FIG. 2i, the removal process 208a may result in a surface topography of superior planarity compared to conventional recipes since the material 221 and 227 (FIG. 2i) may have very similar removal characteristics. Thereafter, the surface modification process 208b may be applied, thereby forming the surface layer 228 in the silicon dioxide base material 222, thereby again imparting silicon nitride-like characteristics to the layer 228. Consequently, the further removal of material of the interlayer dielectric material 220 may also be accomplished on the basis of a removal rate that is more uniform across the entire interlayer dielectric material 220 compared to conventional process strategies. In other cases, a less complex planarization recipe may be applied due to the high degree of similarity of material characteristics across the entire interlayer dielectric material 220. Thereafter, the planarization of the interlayer dielectric material 220 may be continued so as to finally expose the placeholder material 262, while, in other cases, a further process sequence, such as the sequence 207, 208, may be applied if considered appropriate. Consequently, by applying the process sequence 207, 208, any surface non-uniformities obtained upon exposing the placeholder material 262 may be significantly reduced so that the further processing may be continued on the basis of superior process conditions. For example, if considered appropriate, one or more of the above-described surface modification processes may be applied in addition to the process sequences 207, 208, thereby also achieving superior etch resistivity, as discussed above. In other cases, the surface modification of the last process sequence prior to exposing the placeholder material 262 may still be sufficient so as to provide the desired superior etch resistivity. Hence, the further processing, i.e., the replacement of the material 262 with the material system, may also be accomplished on the basis of superior process conditions, as is also discussed above.

As a result, the present disclosure provides manufacturing techniques in which at least one surface modification process, for example a nitridation process, is implemented in a replacement gate approach so as to reduce material loss upon planarizing the interlayer dielectric material and/or upon removing the placeholder material. For example, a nitrogen species may be efficiently incorporated into exposed surface areas of silicon dioxide-based materials by using, for instance, well-established plasma assisted or chemically initiated nitridation process recipes.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a dielectric layer above a gate electrode structure of a transistor, said gate electrode structure comprising a placeholder material;
performing a planarization process so as to remove a portion of said dielectric layer and provide a planarized surface;
performing a surface modification process so as to increase at least an etch resistivity of said planarized surface of said dielectric layer;
exposing a top surface of said placeholder material; and
performing an etch process so as to remove said placeholder material.

2. The method of claim 1, wherein said planarization process is performed so as to expose said top surface of said placeholder material.

3. The method of claim 1, wherein said gate electrode structure comprises a dielectric cap layer formed above said placeholder material and wherein performing said planarization process results in preserving a portion of said dielectric cap layer.

4. The method of claim 3, wherein performing said surface modification process results in a surface layer of increased etch resistivity forming an interface with material of said dielectric layer, wherein a height level of said interface is below a height level of an interface formed between said portion of said dielectric cap layer and said placeholder material.

5. The method of claim 4, further comprising performing a second planarization process so as to expose said top surface in the presence of said surface layer of increased etch resistivity.

6. The method of claim 1, wherein performing said surface modification process comprises applying a plasma ambient so as to incorporate a nitrogen species into exposed surface areas of said dielectric layer.

7. The method of claim 1, wherein performing said surface modification process comprises applying a chemical treatment based on a nitrogen-containing reagent.

8. The method of claim 1, wherein performing said etch process comprises performing a first etch step so as to remove a first portion of said placeholder material prior to performing said surface modification process.

9. The method of claim 1, further comprising performing at least one further surface modification process after forming at least a portion of said dielectric layer and prior to completely removing said placeholder material.

10. A method, comprising:
forming a first portion of an interlayer dielectric material laterally adjacent to a gate electrode structure of a transistor, said gate electrode structure comprising a placeholder material and a dielectric cap layer formed above said placeholder material;
performing a surface modification process so as to form a modified surface layer on said first portion of said interlayer dielectric material;
forming a second portion of said interlayer dielectric material above said first portion;
forming an exposed top surface of said placeholder material by removing a part of at least said second portion and said dielectric cap layer; and
replacing said placeholder material with at least a metal-containing electrode material.

11. The method of claim 10, wherein forming said first portion of said interlayer dielectric material comprises depositing a dielectric material and removing a part thereof so as to adjust a height level of said first portion.

12. The method of claim 11, wherein said height level is adjusted so as to be at or below a height level of an interface formed by said dielectric cap layer and said placeholder material.

13. The method of claim 10, wherein forming said exposed top surface of said placeholder material comprises performing a chemical mechanical planarization process.

14. The method of claim 13, wherein forming said exposed surface of said placeholder material comprises performing a chemical mechanical planarization process.

15. The method of claim 10, wherein performing said surface modification process comprises incorporating a nitrogen species through a surface of said first portion of said interlayer dielectric material.

16. The method of claim 10, further comprising performing at least one further surface modification process after performing said surface modification process.

17. The method of claim 16, wherein said at least one further surface modification process is performed after forming said exposed top surface of said placeholder material.

18. A method, comprising:
forming a dielectric material above and laterally adjacent to a gate electrode structure, said gate electrode structure comprising a placeholder material;
performing a process sequence so as to establish a planarized surface having a modified surface layer, said process sequence comprising performing a planarization process and performing a surface modification process;
repeating said process sequence at least once;
exposing a top surface of said placeholder material; and
replacing said placeholder material at least by a metal-containing electrode material.

19. The method of claim 18, wherein performing said surface modification process comprises incorporating a nitrogen species through said planarized surface of said interlayer dielectric material.

20. The method of claim 19, further comprising forming at least one of said gate electrode structure and said interlayer dielectric material so as to comprise a silicon and nitrogen containing material that is provided above said placeholder material.
